(19) United States
(12) Patent Application Publication
(10) Pub. No.: US 2010/0275076 A1
(43) Pub. Date: Oct. 28, 2010

(54) SEMICONDUCTOR INTEGRATED CIRCUIT AND TESTING METHOD FOR THE SAME

(75) Inventor: Masakazu MAEHARA, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/764,445

(22) Filed: Apr. 21, 2010

(30) Foreign Application Priority Data
Apr. 23, 2009 (JP) 2009-105392

(51) Int. Cl. G01R 31/3177; G06F 11/25

(52) U.S. Cl. 714/726; 714/733; 714/724; 714/E11.155

(57) ABSTRACT

A semiconductor integrated circuit includes: a memory; a logic circuit configured to output an address signal for an address of the memory; and an address control circuit connected with the logic circuit and an address terminal of the memory, and configured to receive a test signal to output one of the address signal from the logic circuit and an output signal having a preset logical value to the address terminal of the memory based on the test signal. The test signal indicates one of a user mode in which a transfer delay fault test is not performed and a test mode in which the transfer delay fault test is performed on a path from the logic circuit to the address terminal of the memory.

### INCORPORATION BY REFERENCE

This application claims a priority on convention based on Japanese Patent Application No. 2009-105392. The disclosure thereof is incorporated herein by reference.

### TECHNICAL FIELD

The present invention relates to a semiconductor integrated circuit and, in particular, a transition delay fault test for the semiconductor integrated circuit.

### BACKGROUND ART

A transition delay fault occurs due to a signal transmission delay increasing on a signal line of a logical circuit. A transition delay fault test is a test in which a test pattern with logical values changed variously is inputted to a test target circuit to check whether a transition delay fault has occurred in the test target circuit. In recent years, with the increase in scale of a semiconductor device, a capacity of Random Access Memory (RAM) included in the semiconductor device is increasing. With the increase in the capacity of RAM, the input/output routes to be tested in a transition delay fault test for the RAM is also increasing. Therefore, there is a demand for a technique capable of easily setting address terminals of the RAM in a short time.

Patent literature 1 discloses a semiconductor integrated circuit capable of easily performing a test on a logic circuit in the periphery of a memory or a test on routes between the memory and a logic circuit by using a scan test scheme.

Referring to FIG. 1, the semiconductor integrated circuit in the patent literature 1 will be described below. FIG. 1 is a diagram showing the configuration of the semiconductor integrated circuit 10 in the patent literature 1. The semiconductor integrated circuit 10 includes a test circuit 12, a logic circuit 14, a test circuit 16, a memory 18, a logic circuit 20, and a test circuit 22.

The test circuit 16 includes multiplexers MUX15 to MUX20 for output signals from the logic circuit 14, that is, data input signals DI[3:0], an address signal input ADDR[3:0], and control signals such as a chip select signal CSN and a write signal WRN. It should be noted that although four multiplexers and two multiplexers are provided as the multiplexers MUX19 and the MUX20, respectively, one multiplexer is shown for each for simplification of the drawing.

The multiplexers MUX15 to MUX20 each have input terminals of 0 to which output signals from the logic circuit 14 are supplied. The multiplexer MUX15 has an input terminal of 1 to which a scan-in signal SCANIN3 is supplied, and the multiplexers MUX16 to MUX18 each have input terminals of 1 to which data output signals DO[3:0] from the memory 18 are supplied. The multiplexers MUX19 and MUX20 each have input terminals of 1 connected to the ground. The multiplexers MUX15 to MUX18 each have selection input terminals to which a scan enable signal SCAN_EN is commonly supplied, and the multiplexers MUX19 and MUX20 each have selection input terminals to which a scan test signal SCAN_TEST is commonly supplied.

Output signals from the multiplexers MUX15 to MUX20 are supplied to input terminals for the data input signals DI[3:0], an input terminal for the address signal input ADDR[3:0], and an input terminal for the control signals. A data output signal DO[0] from the memory 18 is outputted as a scan-out signal SCANOUT3.

The above semiconductor integrated circuit 10 of the patent literature 1 operates as follows. At the time of a normal operation, the scan test signal SCAN_TEST and the scan enable signal SCAN_EN are both set at a low level “L”. Thus, the signals supplied to their input terminals of 0, that is, the data input signal DI[3:0], the address signal ADDR[3:0], and the control signals are outputted from the multiplexers MUX15 to MUX20.

At the time of a test operation, the scan test signal SCAN_TEST is set to a high level “H”. The signals supplied to their input terminals of 1, that is, the low levels are outputted from the multiplexers MUX19 and MUX20. Thus, the address signals ADDR[3:0] supplied to the memory 18 are fixed to “0000 (binary number)”, and the control signals are both fixed to an enable state. In this case, in the memory 18, the data input signals DI[3:0] supplied to the input terminals are written as a data in the address of “0000 (binary number)” in synchronization with a clock signal CLK. Also, the data written in the address of “0000 (binary number)” of the memory is outputted as it is, from output terminals for data output signal DO[3:0]. That is, the memory 18 operates in a manner similar to that of a flip-flop. Thus, the test circuit 16 and the memory 18 form a scan chain.

The scan chain formed from the test circuit 16 and the memory 18 can be used as an observation scan chain for observing output signals from the logic circuit 14, and also can be used as a control scan chain for setting input signals to the logic 20 in a predetermined state.

According to the semiconductor integrated circuit of the patent literature 1, the address signals supplied to the memory are fixed by the test circuit 16 to specify a predetermined address at the time of a test operation so that data is written in the specified address of the memory in synchronization with a clock signal, and a circuit for each of data bits in the specified address of the memory is used as a flip-flop to form a scan chain. Therefore, a test on a logic circuit in the periphery of the memory can be performed in a circuit configuration having a smaller overhead compared with those in conventional various schemes.

### Citation List:

Patent literature 1: JP 2004-279310A

### SUMMARY OF THE INVENTION

However, in the semiconductor integrated circuit 10 of the patent literature 1 , a test cannot be performed on a route from the logic circuit 14 to the address signals ADDR[3:0] of the memory 18. The semiconductor integrated circuit 10 has a configuration in which the address signals ADDR[3:0] of the memory 18 are fixed by the multiplexer MUX19, thereby improving the ease of testing on data input signals DI[3:0] in the memory 18. Here, the ease of testing represents a degree of ease of generating a test pattern by using a test-pattern generation tool or the like. Since a selection control terminal of the multiplexer MUX19 is always supplied with the SCAN _TEST signal of “1” at the time of the test operation, a route from the input terminal of 0 to the output terminal of the multiplexer MUX19 is never activated. That is, since the route from the logic circuit 14 to the input terminals for the address signals ADDR[3:0] of the memory 18 is logically broken, a signal supplied from the logic circuit 14 propagates merely up to the multiplexer MUX19, and a value of “0” or “1” cannot be propagated to the address terminals of the memory 18.

Moreover, in the semiconductor integrated circuit 10 of the patent literature 1, it is described that the data signals DI[3:0] and the address signals ADDR[3:0] can be tested in a time-division manner by calculating exclusive OR of the address signals ADDR[3:0] and the data input signals DI[3:0] by using XOR circuits at the time of the test operation. However, in such a case, since the multiplexer MUX19 cannot pass the value of “0” or “1” supplied from the logic circuit 14 to the output of the multiplexer MUX19, the XOR circuit must be inserted between the logic circuit 14 and the multiplexer MUX19. Therefore, a RAM transition delay test cannot be performed on a route between the multiplexer MUX19 and the input terminals of the address signals ADDR[3:0] of the memory 18.

In an aspect of the present invention, a semiconductor integrated circuit includes: a memory; a logic circuit configured to output an address signal for an address of the memory; and an address control circuit connected with the logic circuit and an address terminal of the memory, and configured to receive a test signal to output one of the address signal from the logic circuit and an output signal having a preset logical value to the address terminal of the memory based on the test signal. The test signal indicates one of a user mode in which a transfer delay fault test is not performed and a test mode in which the transfer delay fault test is performed on a path from the logic circuit to the address terminal of the memory.

In another aspect of the present invention, a test method of a semiconductor integrated circuit, is achieved by receiving an address signal for an address of a memory from a logic circuit, an output signal having a preset logical value and a test signal; by selecting one of the address signal and the output signal based on the test signal; and by outputting the selected signal to an address terminal of the memory. The test signal indicates one of the user mode in which a transfer delay fault test is not performed and a test mode in which the transfer delay fault test is performed on a path from the logic circuit to the address terminal of the memory. The address signal is selected in a user mode and the output signal is selected in a test mode.

According to the present invention, when a transition delay fault test is performed in a semiconductor integrated circuit including a RAM, an output from a logic circuit disposed in a stage proceeding to a RAM can be propagated to an address terminal of the RAM. Therefore, a transition delay fault test from the logic circuit to the address terminal of the RAM can be performed.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a diagram of a configuration of a conventional semiconductor integrated circuit;

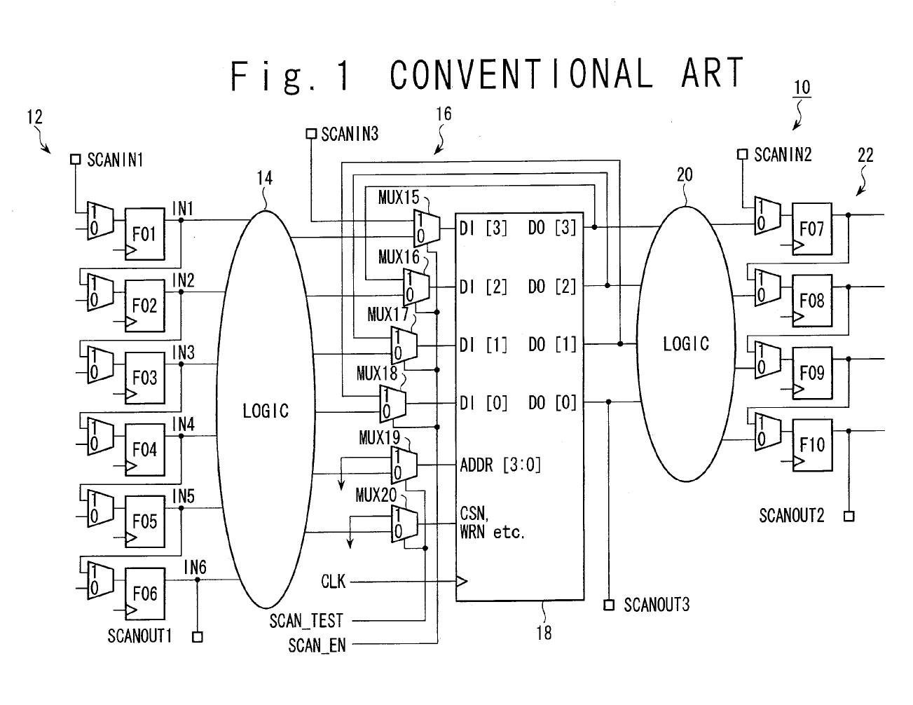

FIG. 2 is a block diagram showing a configuration of a semiconductor integrated circuit according to a first embodiment of the present invention;

FIG. 3 is a diagram of an example of a truth table of an address control circuit in the semiconductor control circuit of the first embodiment;

FIG. 4 is a block diagram showing a configuration of the semiconductor integrated circuit according to a second embodiment of the present invention;

FIG. 5 is a block diagram showing a configuration of the semiconductor integrated circuit according to a third embodiment of the present invention;

FIG. 6 is an example of a truth table of the address control circuit in the semiconductor integrated circuit of the third embodiment;

FIG. 7 is a block diagram showing a configuration of the semiconductor integrated circuit according to a fourth embodiment of the present invention;

FIG. 8 is a block diagram showing a configuration of the semiconductor integrated circuit according to a fifth embodiment of the present invention;

FIG. 9 is a diagram of an example of a truth table of the address control circuit in the semiconductor integrated circuit of the fifth embodiment; and

FIG. 10 is a block diagram showing a configuration of the semiconductor integrated circuit according to a sixth embodiment of the present invention.

### DESCRIPTION OF EMBODIMENTS

Hereinafter, a semiconductor integrated circuit according to the present invention will be described in detail with reference to the attached drawings.

### First Embodiment

First, the semiconductor integrated circuit according to a first embodiment of the present invention will be described.

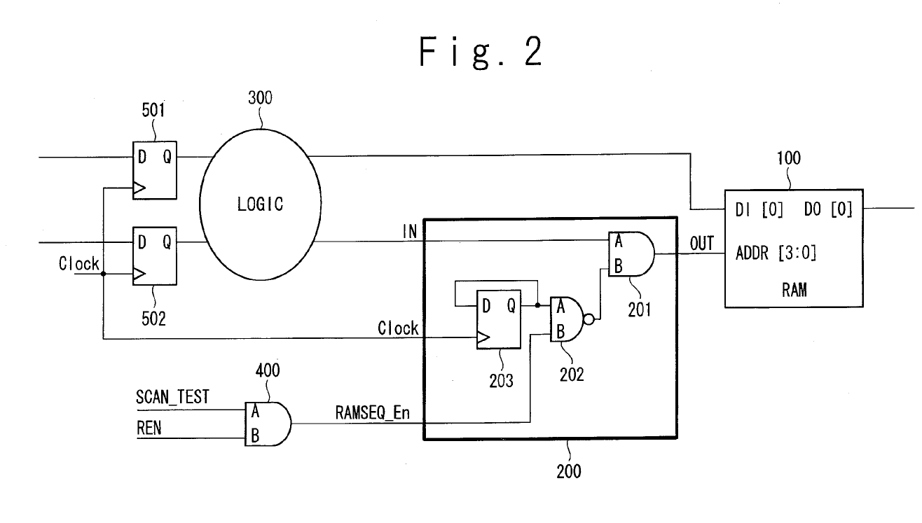

First, a configuration of the semiconductor integrated circuit according to the present embodiment will be described. FIG. 2 is a block diagram showing the configuration of the semiconductor integrated circuit in the present embodiment. It should be noted that a scan-chain configuration for a transition delay failure test and a scan-enable terminal do not relate directly to the present invention and therefore the description of them is omitted in the following description.

The semiconductor integrated circuit in the present embodiment includes a Random Access Memory (RAM) 100, an address control circuit 200 for the RAM 100, a logic circuit 300, scan flip-flops 501 and 502, and an AND gate 400.

The RAM 100 has a data input signal terminal DI[0], address signal terminals ADDR[3:0] and a data output signal terminal DO[0]. The data input signal terminal DI[0] is connected to the logic circuit 300 to receive the output from the logic circuit 300. The address signal terminals ADDR[3:0] are connected to an output terminal OUT of the address control circuit 200 to receive an output from the address control circuit 200. The data output signal terminal DO[0] is connected to a processing unit in a subsequent stage (not shown) to output an output data of the RAM 100. Here, although not shown for simplification of description, the RAM 100 includes more data input signal terminals DI and data output signal terminals DO in practice. Also, the address signal terminals ADDR[3:0] includes four terminals in total, but these terminals are not shown in the drawing. The address signal terminals ADDR[3:0] are collected referred to as an address terminal, hereinafter.

The scan flip-flop 501 and the scan flip-flop 502 configure a scan chain for performing a transition delay fault test. As described above, a scan-chain configuration and a scan enable terminal of the semiconductor integrated circuit in the present embodiment are omitted in FIG. 2. An input D of the scan flip-flop 501 and an input D of the scan flip-flop 502 are connected to a circuit in a previous stage (not shown). A clock input of the scan flip-flop 501 and a clock input of the scan flip-flop 502 are connected to a processing unit (not shown) for a clock signal Clock. An output Q of the scan flip-flop 501 and an output Q of the scan flip-flop 502 are connected to the logic circuit 300.

The logic circuit 300 conceptually represents a logic circuit inside of the semiconductor integrated circuit in the present embodiment. The logic circuit 300 processes the received outputs Q of the scan flip-flops 501 and 502 to output signals. The output from the logic circuit 300 is connected to the data input signal terminal DI[0] of the RAM 100 and the input IN of the address control circuit 200.

Based on a signal SCAN_TEST and a signal REN, the AND gate 400 outputs a signal RAMSEQ_En. The input A of the AND gate 400 is connected to the processing unit in the previous stage (not shown) to receive the signal SCAN_TEST. An input B of the AND gate 400 is connected to the processing unit in the preceding stage (not shown) to receive the signal REN. The output from the AND gate 400 is connected to the address control circuit 200 to output the signal RAMSEQ_En.

The address control circuit 200 includes an AND gate 201, an NAND gate 202, and a scan flip-flop 203. An input A of the AND gate 201 receives the output from the logic circuit 300 as the input IN of the address control circuit 200. An input B of the AND gate 201 receives an output from the NAND gate 202. An output from the AND gate 201 is connected to the address signal terminal ADDR[3:0] of the RAM 100 via the output OUT of the address control circuit 200. An input A of the NAND gate 202 is connected to an output Q of the scan flip-flop 203. An input B of the NAND gate 202 receives the signal RAMSEQ_En from the AND gate 400. The scan flip-flop 203 receives the clock signal Clock from the processing unit (not shown). A data input D of the scan flip-flop 203 is connected to the output Q of the scan flip-flop 203. Here, an initial value of the scan flip-flop 203 is set by a scan chain omitted in the drawing.

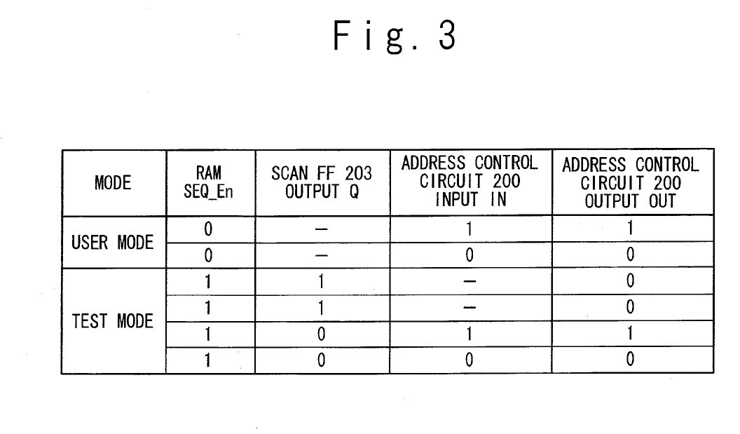

Next, an operation method of the semiconductor integrated circuit of the present embodiment will be described. FIG. 3 is a diagram showing an example of a truth table of the address control circuit 200 in the semiconductor control circuit of the present embodiment.

The semiconductor integrated circuit of the present embodiment has a user mode and a test mode, the operation is switched between these modes. In the user mode, the circuit operates in accordance with a circuit specification defined by a user, and a test circuit incorporated in the semiconductor integrated circuit does not operate. In the test mode, a DFT (design-for-testability) circuit incorporated in the semiconductor integrated circuit operates and the circuit operates to generate a test pattern.

In the user mode, the address control circuit 200 receives a logical value to be supplied to the input IN to output as the output OUT of the address control circuit 200. On the other hand, in the test mode, the address control circuit 200 can fix the logical value to a fixed value as the output OUT of the address control circuit 200, and can also receive the logical value to be supplied to the input IN to output as the output OUT of the address control circuit 200.

In the present embodiment, the address control circuit 200 sets the signal RAMSEQ_En to the logical value of “0” to enter the user mode. The signal RAMSEQ_En is controlled based on the logical value of the REN signal and that of the signal SCAN_TEST supplied to the AND gate 400. The NAND gate 202 receives the logical value of “0” as the signal RAMSEQ_En at its input B. Here, when the logical value of “1” or “0” is supplied from the output Q of the scan flip-flop 203 to the input A of the NAND gate 202, the output from the NAND gate 202 has the logical value of “1”. Therefore, the output from the AND gate 201 is determined based on the logical value to be supplied to the input A of the AND gate 201. The input A of the AND gate 201 is connected to the input IN of the address control circuit 200. The AND gate 201 receives at the input A, the output signal from the logic circuit 300 via the input IN of the address control circuit 200, and outputs the logical value of the output signal from the logic circuit 300 as the output OUT of the address control circuit 200. With this, the address control circuit 200 can transfer the output from the logic circuit 300 to the address signal terminal ADDR[3:0] of the RAM 100. Here, in the user mode, the address control circuit 200 can transfer the output from the logic circuit 300 to the input terminal of the address signals ADDR[3:0] in the RAM 100 irrespectively of whether the output from the scan flip-flop 203 has a logical value of “0” or “1”.

On the other hand, in the present embodiment, the address control circuit 200 enters the test mode by setting the signal RAMSEQ_En to the logical value of “1”. The signal RAMSEQ_En is controlled based on the logical values of the signal REN and the signal SCAN_TEST supplied to the AND gate 400. The NAND gate 202 receives the logical value of “1” at the input B. Here, when the logical value of “1” is supplied from the output Q of the scan flip-flop to the input A of the NAND gate 202, the output from the NAND gate 202 takes the logical value of “0”. Therefore, the output from the AND gate 201 is determined based on the logical value of “0” irrespectively of the input A of the AND gate 201. With this, the address control circuit 200 can transfer the logical value of “0” to the address signal terminal ADDR[3:0] of the RAM 100. Also, in the test mode, when the logical value of “0” is supplied from the output Q of the scan flip-flop 203 to the input A of the NAND gate 202, the output from the NAND gate 202 takes the logical value of “1”. Therefore, the output from the AND gate 201 is determined in accordance with the logical value supplied to the input A of the AND gate 201. The input A of the AND gate 201 is connected to the input IN of the address control circuit 200. Therefore, the address control circuit 200 can transfer the output from the logic circuit 300 to the address signal terminal ADDR[3:0] of the RAM 100. It should be noted that the address control circuit 200 can achieve effects similar to those above even when the AND gate 201 is changed to an OR gate and the NAND gate 202 is changed to an AND gate.

In this way, according to the semiconductor integrated circuit in the present embodiment, the output Q of the scan flip-flop 203 in the address control circuit 200 is set to the logical value of the input IN to the output OUT in the address control circuit 200 can be activated. Thus, the output from the logic circuit 300 can be transferred to the address signal terminal ADDR[3:0] of the RAM 100, and a transition delay fault test can be performed on the route from the logic circuit 300 to the address signal terminal ADDR[3:0].

### Second Embodiment

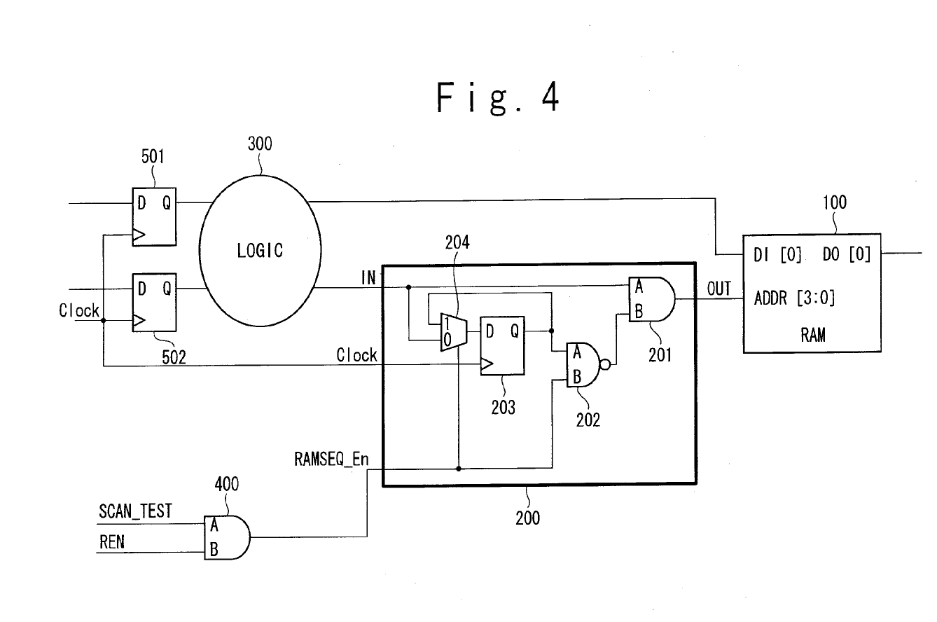

Next, the semiconductor integrated circuit according to a second embodiment of the present invention will be described. First, the configuration of the semiconductor integrated circuit in the present embodiment will be described. FIG. 4 is a diagram of the configuration of the semiconductor integrated circuit in the second embodiment. It should be noted that the scan-chain configuration for the transition delay failure test and the scan-enable terminal are not involved in the operation of the present invention and therefore the description of them is omitted in the following description. The semiconductor integrated circuit in the present embodiment is approximately similar to that in the first embodiment. Therefore, the description of the same portions as those in the first embodiment is omitted, and portions different from those in the first embodiment will be mainly described.

The semiconductor integrated circuit of the present embodiment can perform a stuck-at fault test in addition to the transition delay fault test in the semiconductor integrated circuit of the first embodiment. Here, the stuck-at fault is a fault in which the output value is fixed irrespectively of a test pattern supplied to a circuit. The stuck-at fault test is a test for checking whether a stuck-at fault has occurred in a target circuit.

As in the first embodiment, the semiconductor integrated circuit in the present embodiment includes the Random Access Memory (RAM) 100, the address control circuit 200 for the RAM 100, the logic circuit 300, the scan flip-flops 501 and 502, and the AND gate 400. The semiconductor integrated circuit of the present embodiment is different from that of the first embodiment in the configuration of the address control circuit 200. Therefore, the description of the configurations of components other than the address control circuit 200 is omitted.

The address control circuit 200 of the present embodiment includes an AND gate 201, an NAND gate 202, a scan flip-flop 203, and a multiplexer 204. An output from the AND gate 201 is connected to the output OUT of the address control circuit 200. An input A of the AND gate 201 is connected to the input IN of the address control circuit 200. An input B of the AND gate 201 is connected to an output from the NAND gate 202. An input A of the NAND gate 202 is connected to an output Q of the scan flip-flop 203. An input B of the NAND gate 202 is connected to the signal RAMSEQ_En of the address control circuit 200. A clock input of the scan flip-flop 203 is connected to a clock input Clock of the address control circuit 200. A data input D of the scan flip-flop 203 is connected to an output from the multiplexer 204. An input 1 of the multiplexer 204 is connected to the output Q of the scan flip-flop 203. An input 2 of the multiplexer 204 is connected to the input IN of the address control circuit 200. A selection control input of the multiplexer 204 is connected to the signal RAMSEQ_En of the address control circuit 200.

In the present embodiment, the scan flip-flop 203 is used also as an observation scan flip-flop for a stuck-at fault test. In the present embodiment, by adding the multiplexer 204, a route from the input IN of the address control circuit 200 to the data input D of the scan flip-flop 203 is ensured.

Next, an operation method of the semiconductor integrated circuit of the present embodiment will be described. The operation of the address control circuit 200 in the present embodiment will be described based on the truth table shown in FIG. 3. However, the semiconductor integrated circuit of the present embodiment is different in configuration from that of the first embodiment, and therefore its operation method is different. Thus, portions different from those in the first embodiment are mainly described.

The multiplexer 204 determines the input 1 or the input 2 as the output in accordance with the logical value of the signal RAMSEQ_En. In the present embodiment, when the transition delay fault test is performed, the logical value of the signal RAMSEQ_En is set to “1”. When the signal RAMSEQ_En has the logical value of “1”, the multiplexer 204 selects the input 1 as the output. The input 1 of the multiplexer 204 is connected to the output D of the scan flip-flop 203. In this case, the operation is similar to that of the address control circuit 200 of the first embodiment.

On the other hand, when the stuck-at fault test is performed, the logical value of the signal RAMSEQ_En is set to “0”. When the signal RAMSEQ_En has the logical value of “0”, the multiplexer 204 selects the input 0 as the output signal. The input 0 of the multiplexer 204 is connected to the input IN of the address control circuit 200. With this, a route from the input IN of the address control circuit 200 via the input 0 of the multiplexer 204 to the scan flip-flop 203 is activated. Therefore, the scan flip-flop 203 can receive at the data input D an output signal outputted from the logic circuit 300 via the input IN of the address control circuit 200, and the scan flip-flop 203 can be used as an observation scan flip-flop in the stuck-at fault test.

In this way, according to the semiconductor integrated circuit in the present embodiment, the transition delay fault test can be performed based on the signal RAMSEQ_En having the logical value of “1”. Also, when the output Q of the scan flip-flop 203 in the address control circuit 200 is set to the logical value of “0”, the route from the input IN to the output OUT in the address control circuit 200 can be activated even in the test mode. Therefore, the output from the logic circuit 300 can be transferred to the address signal terminal ADDR[3:0] of the RAM 100, and the transition delay fault test can be performed on the route from the logic circuit 300 to the address signal terminal ADDR[3:0].

Also, according to the semiconductor integrated circuit in the present embodiment, the stuck-at fault test can be performed based on the signal RAMSEQ_En having the logical value of “0”. In this case, the scan flip-flop 203 can be used as an observation scan flip-flop for the stuck-at fault test. With this, the address control circuit 200 is not required to additionally include a separate observation scan flip-flop for the stuck-at fault test, thereby complicated interconnections can be avoided.

### Third Embodiment

Next, the semiconductor integrated circuit according to a third embodiment of the present invention will be described.

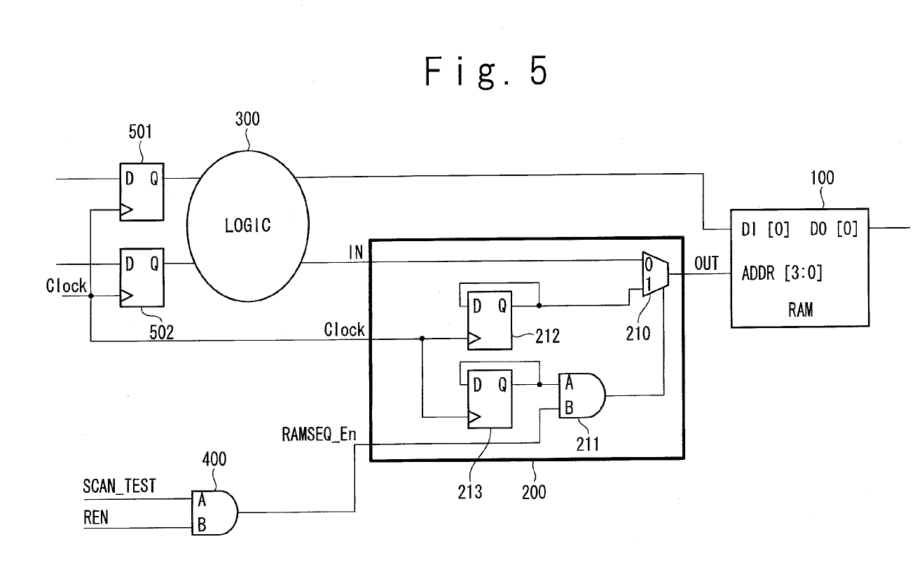

First, the configuration of the semiconductor integrated circuit in the present embodiment will be described. FIG. 5 is a block diagram showing the configuration of the semiconductor integrated circuit in the present embodiment. It should be noted that the scan-chain configuration for the transition delay failure test and the scan-enable terminal are not involved in the operation of the present invention and therefore the description of them is omitted in the following description. The semiconductor integrated circuit in the present embodiment is approximately similar to that in the first embodiment. Therefore, the description of the same portions as those in the first embodiment is omitted, and portions different from those in the first embodiment are mainly described.

The semiconductor integrated circuit in the present embodiment includes the Random Access Memory (RAM) 100, the address control circuit 200 for the RAM 100, the logic circuit 300, scan flip-flops 501 and 502, and the AND gate 400. The semiconductor integrated circuit of the present embodiment is different from that of the first embodiment in the configuration of the address control circuit 200. Therefore, the configurations of components other than the address control circuit 200 are not described herein.

The address control circuit 200 of the present embodiment includes a multiplexer 210, an AND gate 211, and scan flip-flops 212 and 213. An input 0 of the multiplexer 210 is connected to the input IN of the address control circuit 200. An input 1 of the multiplexer 210 is connected to an output Q of the scan flip-flop 212. An output from the multiplexer 210 is connected to the output OUT of the address control circuit 200. The selection control input of the multiplexer 210 is connected to the output from the AND gate 211. That is, based on the output from the AND gate 211, the multiplexer 210 selects either one of the output from the logic circuit 300 to be supplied to the input 0 via the input IN of the address control circuit 200 and the output Q of the scan flip-flop 212 to be supplied to the input 1. The input A of the AND gate 211 is connected to the output Q of the scan flip-flop 213. The input B of the AND gate 211 is connected to the signal RAMSEQ_En of the address control circuit 200. The data input D of the scan flip-flop 212 is connected to the output Q of the scan flip-flop 212. The clock input of the scan flip-flop 212 is connected to the clock input Clock of the address control circuit 200. The data input D of the scan flip-flop 213 is connected to the output Q of the scan flip-flop 213. The clock input of the scan flip-flop 213 is connected to the clock input Clock of the address control circuit 200.

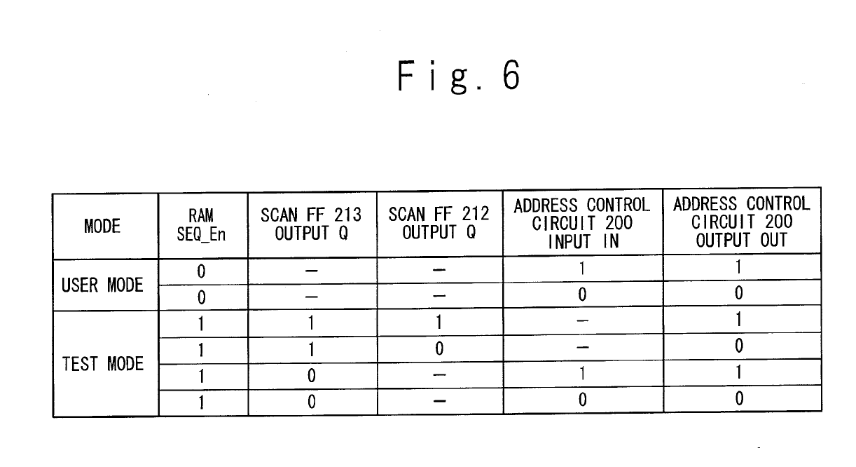

Next, an operation method of the semiconductor integrated circuit of the present embodiment will be described. FIG. 6 is a diagram showing an example of a truth table of the address control circuit 200 in the semiconductor integrated circuit of the present embodiment.

As in the first embodiment, the semiconductor integrated circuit of the present embodiment has the user mode and the test mode and the operation is switched between these modes. In the user mode, the address control circuit 200 outputs the logical value to be supplied to the input IN as the output OUT of the address control circuit 200. On the other hand, in the test mode, the address control circuit 200 can fix the logical value of the output OUT of the address control circuit 200 to a fixed value, and also can output a logical value to be supplied to the input IN as the output OUT of the address control circuit 200.

FIG. 6 shows an example of the truth table of the address control circuit 200. In the present embodiment, the address control circuit 200 sets the signal RAMSEQ_En to the logical value of “0” to enter the user mode. The signal RAMSEQ_En is controlled based on the logical value of the signal REN and that of the signal SCAN_TEST supplied to the AND gate 400. The AND gate 211 receives the signal RAMSEQ_En having the logical value of “0” at its input B. Here, even if the scan flip-flop 213 supplies either one of the logical values “1” or “0” from the output Q to the input A of the AND gate 211, the output from the AND gate 211 has the logical value of “0”. In this case, the multiplexer 210 selects the input to the input 0 as the output. Therefore, the output from the multiplexer 210 is determined according to the logical value supplied to the input 0. The input 0 of the multiplexer 210 is connected to the input IN of the address control circuit 200. The multiplexer 210 receives at its input 0, the output signal from the logic circuit 300 via the input IN of the address control circuit 200, and outputs the logical value of the output signal from the logic circuit 300 as the output OUT of the address control circuit 200. With this, the address control circuit 200 can transfer the output from the logic circuit 300 to the address signal terminal ADDR[3:0] of the RAM 100. Here, in the user mode, the address control circuit 200 can transfer the output from the logic circuit 300 to the address signal terminal ADDR[3:0] of the RAM 100 irrespectively of whether the output from the scan flip-flop 213 has the logical value of “0” or “1”.

On the other hand, in the present embodiment, the address control circuit 200 enters the test mode by setting the signal RAMSEQ_En to the logical value of “1”. The signal RAMSEQ_En is controlled based on the logical value of the signal REN and that of the signal SCAN_TEST supplied to the AND gate 400. The AND gate 211 receives the logical value of “1” at the input B. In this case, when the logical value of “1” is supplied from the output Q of the scan flip-flop 213 to the input A of the AND gate 211, the output from the AND gate 211 has the logical value of “1”. In this case, the multiplexer 210 selects the input 1 as the output. Therefore, the output from the multiplexer 210 is determined in accordance with the logical value supplied to the input 1. The input 1 of the multiplexer 210 is connected to the output Q of the scan flip-flop 212. Here, when the logical value of “1” or the logical value of “0” is supplied from the output Q of the scan flip-flop 212 to the input 1 of the multiplexer 210, the output OUT of the address control circuit 200 is fixed to the output Q of the scan flip-flop 212 irrespectively of the logical value supplied to the input IN.

Also, when the logical value of “0” is supplied from the output Q of the scan flip-flop 213 to the input A of the AND gate 211, the output from the AND gate 211 has the logical value of “0”. In this case, the multiplexer 210 selects the input 0 as the output. The input 0 of the multiplexer 210 is connected to the input IN of the address control circuit 200. The multiplexer 210 receives at its input 0 the output signal from the logic circuit 300 via the input IN of the address control circuit 200, and outputs the logical value of the output signal from the logic circuit 300 as the output OUT of the address control circuit 200. With this, the address control circuit 200 can transfer the output from the logic circuit 300 to the address signal terminal ADDR[3:0] of the RAM 100.

In this way, according to the semiconductor integrated circuit in the present embodiment, when the output Q of the scan flip-flop 213 in the address control circuit 200 is set to the logical value of “0”, the route from the input IN to the output OUT in the address control circuit 200 can be activated even in the test mode. Therefore, the output from the logic circuit 300 can be transferred to the address signal terminal ADDR[3:0] of the RAM 100, and the transition delay fault test can be performed on the route from the logic circuit 300 to the address signal terminal ADDR[3:0].

Furthermore, according to the semiconductor integrated circuit in the present embodiment, the address control circuit 200 can determine of the logical values to be supplied to the address signal terminal ADDR[3:0] of the RAM 100 based on the output Q of the scan flip-flop 212. Therefore, even when the logical values to be supplied are changed, the configuration of the address control circuit 200 is not required to be changed, thereby suppressing an increase in design Turn Around Time (TAT).

### Fourth Embodiment

Next, the semiconductor integrated circuit according to a fourth embodiment of the present invention will be described.

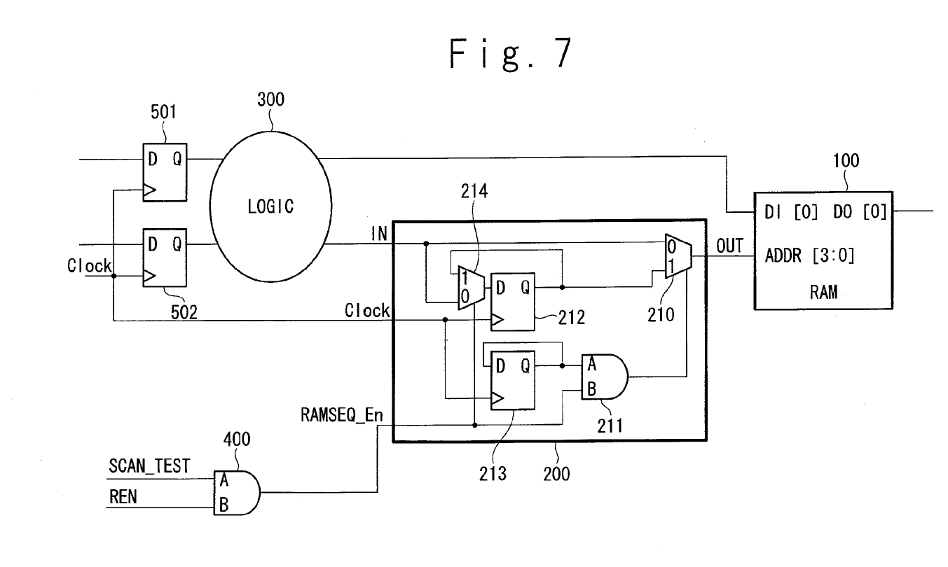

First, the configuration of the semiconductor integrated circuit in the present embodiment will be described. FIG. 7 is a diagram showing the configuration of the semiconductor integrated circuit in the present embodiment. It should be noted that the scan-chain configuration in the transition delay failure test and the scan-enable terminal are not involved in the operation of the present invention and therefore the description of them is omitted in the following description. The semiconductor integrated circuit in the present embodiment is similar to that in the third embodiment. Therefore, the same portions as those in the third embodiment are not described herein, and portions different from those in the third embodiment will be mainly described. The semiconductor integrated circuit of the present embodiment can perform the stuck-at fault test in addition to the transition delay fault test in the semiconductor integrated circuit of the third embodiment.

As in the third embodiment, the semiconductor integrated circuit in the present embodiment includes the Random Access Memory (RAM) 100, the address control circuit 200 for the RAM 100, the logic circuit 300, the scan flip-flops 501 and 502, and the AND gate 400. The semiconductor integrated circuit of the present embodiment is different from that of the first embodiment in the configuration of the address control circuit 200. Therefore, the configurations of components other than the address control circuit 200 are not described herein.

The address control circuit 200 of the present embodiment includes a multiplexer 210, an AND gate 211, and scan flip-flops 212 and 213, and a multiplexer 214. An input 0 of the multiplexer 210 is connected to the input IN of the address control circuit 200. An input 1 of the multiplexer 210 is connected to an output Q of the scan flip-flop 212. An output from the multiplexer 210 is connected to the output OUT of the address control circuit 210. A selection control input of the multiplexer 210 is connected to an output from the AND gate 211. That is, based on the output from the AND gate 211, the multiplexer 210 selects either one of the output from the logic circuit 300 to be supplied to the input 0 via the input IN of the address control circuit 200 and the output Q of the scan flip-flop 212 to be supplied to the input 1. An input A of the AND gate 211 is connected to an output Q of the scan flip-flop 213. An input B of the AND gate 211 is connected to the signal RAMSEQ_En of the address control circuit 200. A data input D of the scan flip-flop 212 is connected to an output from the multiplexer 214. A clock input to the scan flip-flop 212 is connected to the clock input Clock of the address control circuit 200. An input 1 of the multiplexer 214 is connected to the output Q of the scan flip-flop 212. An input 0 of the multiplexer 214 is connected to the input IN of the address control circuit 200. A selection control input of the multiplexer 214 is connected to the signal RAMSEQ En of the address control circuit 200. The data input D of the scan flip-flop 213 is connected to the output Q of the scan flip-flop 213. A clock input to the scan flip-flop 213 is connected to the clock input Clock of the address control circuit 200.

In the present embodiment, the scan flip-flop 213 is used also as an observation scan flip-flop for the stuck-at fault test. In the present embodiment, by adding the multiplexer 214, a route from the input IN of the address control circuit 200 to the data input D of the scan flip-flop 213 is ensured.

Next, an operation method of the semiconductor integrated circuit of the present embodiment will be described. An input and output of the address control circuit 200 in the present embodiment are similar to those as shown in a truth table depicted in FIG. 6. However, the semiconductor integrated circuit of the present embodiment is different in configuration from the third embodiment, and therefore its inner operation method is different. Thus, portions different from those in the third embodiment will be mainly described.

The multiplexer 214 of the present embodiment determines the input 1 or the input 2 in accordance with the logical value of the RAMSEQ_En signal. In the present embodiment, when the transition delay fault test is performed, the logical value of the signal RAMSEQ_En is set to “1”. When the signal RAMSEQ_En has the logical value of “1”, the multiplexer 214 selects the input 1 as the output. The input 1 of the multiplexer 214 is connected to the output D of the scan flip-flop 212. In this case, the operation is similar to that of the address control circuit 200 of the third embodiment.

On the other hand, when the stuck-at fault test is performed, the logical value of the signal RAMSEQ_En is set to “0”. When the signal RAMSEQ_En has the logical value of “0”, the multiplexer 204 selects the input 0 as the output. The input 0 of the multiplexer 204 is connected to the input IN of the address control circuit 200. With this, a route from the input IN of the address control circuit 200 via the input 0 of the multiplexer 204 to the scan flip-flop 203 can be activated. Therefore, the scan flip-flop 203 can receives at the data input D the output signal outputted from the logic circuit 300 via the input IN of the address control circuit 200, and the scan flip-flop 203 can be used as an observation scan flip-flop in the stuck-at fault test.

In this way, according to the semiconductor integrated circuit in the present embodiment, the transition delay fault test can be performed when the logical value of the signal RAMSEQ_En is set to “1”. Also, when the output Q of the scan flip-flop 213 in the address control circuit 200 is set to the logical value of “0”, the route from the input IN to the output OUT of the address control circuit 200 can be activated even in the test mode. Therefore, the output from the logic circuit 300 can be transferred to the address signal terminal ADDR[3:0] of the RAM 100, and the transition delay fault test can be performed on the route from the logic circuit 300 to the address signal terminal ADDR[3:0].

Also, according to the semiconductor integrated circuit in the present embodiment, the address control circuit 200 can determine either one of the logical values of “0” and “1” to be supplied to the address signal terminal ADDR[3:0] of the RAM 100 based on the output Q of the scan flip-flop 212. Therefore, even when the logical value to be supplied is changed, the configuration of the address control circuit 200 is not required to be changed, thereby suppressing an increase in design TAT.

Furthermore, according to the semiconductor integrated circuit in the present embodiment, the stuck-at fault test can be performed when the logical value of the signal RAMSEQ_En is set to “0”. In this case, the scan flip-flop 203 can be used as an observation scan flip-flop for the stuck-at fault test. With this, the address control circuit 200 is not required to additionally include a separate observation scan flip-flop for the stuck-at fault test, thereby complicated interconnections can be avoided.

### Fifth Embodiment

Next, the semiconductor integrated circuit according to a fifth embodiment of the present invention will be described.

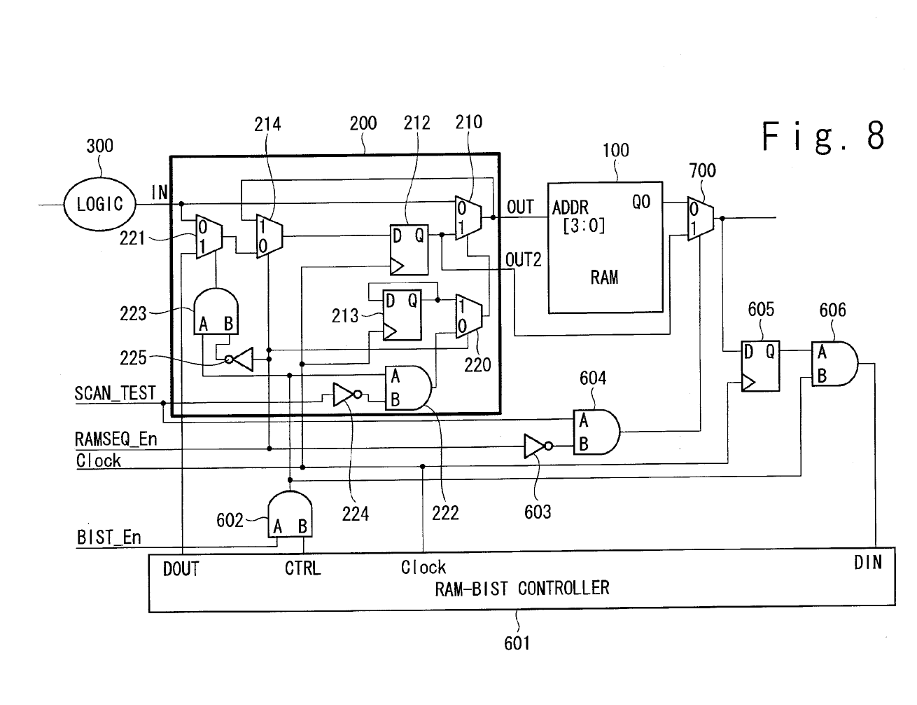

First, the configuration of the semiconductor integrated circuit in the present embodiment will be described. FIG. 8 is a diagram showing the configuration of the semiconductor integrated circuit in the present embodiment. It should be noted that the scan-chain configuration for the transition delay failure test is not involved in the operation of the present invention and therefore the description of it is omitted in the following description. The semiconductor integrated circuit in the present embodiment is approximately similar to that in the fourth embodiment. Therefore, the same portions as those in the fourth embodiment are not described herein, and portions different from those in the fourth embodiment will be mainly described.

The semiconductor integrated circuit of the present embodiment can further perform a Random Access Memory-Built In Self Test (RAM-BIST) in addition to the transition delay fault test and the stuck-at fault test in the semiconductor integrated circuit of the fourth embodiment. Here, the RAM-BIST is a test in which a test pattern is transferred and received by a tester via a test target circuit, the tester including a generating unit and a determining unit which are provided in a semiconductor integrated circuit. The generating unit generates the test pattern and supplies the test pattern to the test target circuit. The determining unit holds expected values of output patterns corresponding to the test patterns in advance and, upon reception of one output pattern from the target circuit, compares the output pattern with the expected values to determine whether a fault has occurred. In the RAM-BIST, since the generating unit and the determining unit are incorporated in the semiconductor integrated circuit, the number of times of signal exchange of between the tester and the test target circuit can be reduced.

As in the fourth embodiment, the semiconductor integrated circuit in the present embodiment includes the Random Access Memory (RAM) 100, the address control circuit 200 for the RAM 100, and the logic circuit 300, and a RAM-BIST controller 601, AND gates 602, 604, and 606, an inverter gate 603, a scan flip-flop 604, and a multiplexer 700. Here, the scan flip-flops 501 and 502 and the AND gate 400 are omitted in the drawing. Also, the RAM 100 and the logic circuit 300 are similar to those of the fourth embodiment, and therefore are not described herein.

The input IN of the address control circuit 200 is connected to the output from the logic circuit 300. The output OUT of the address control circuit 200 is connected to the address signal terminal ADDR[3:0] of the RAM 100. An output OUT2 of the address control circuit 200 is connected to an input 1 of the multiplexer 700. Also, the address control circuit 200 is connected to circuits in previous stages (not shown) to receive inputs of the signal SCAN_TEST, the signal RAMSEQ_En, and the clock signal Clock from these circuits. A BIST pattern input of the address control circuit 200 is connected to an output DOUT of the controller 601. A BIST_CTRL signal input of the address control circuit 200 is connected to an output from the AND gate 602.

The controller 601 has the output DOUT for outputting a test pattern, a CTRL output for outputting a control signal, a Clock input for the clock signal, and an input DIN for an output pattern corresponding to the test pattern. When a RAM-BIST test is performed, the controller 601 outputs the logical value of “1” from the CTRL output and also outputs a test pattern from the output DOUT to receive an output pattern corresponding to the test pattern from the test target circuit at the input DIN. The controller 601 determines whether a fault has occurred, based on whether the output pattern supplied to the input DIN matches any check pattern stored in advance. Thus, the controller 601 is a general RAM-BIST tester, and therefore is not described in detail herein.

The test pattern output DOUT of the controller 601 is connected to an input 1 of the multiplexer 221 in the address control circuit 200. The CTRL signal output of the controller 601 is connected to an input B of the AND gate 602. The controller 601 receives the clock signal Clock. The input DIN of the controller 601 is connected to an output from the AND gate 606. An input A of the AND gate 602 receives the signal BIST_En. An input B of the AND gate 602 is connected to the CTRL signal output of the controller 601. An output from the AND gate 602 is connected to an input A of the AND gate 223 and an input A of the AND gate 222. The inverter gate 603 receives the signal RAMSEQ_En. An input A of the AND gate 604 receives the signal SCAN_TEST. An input B of the AND gate 604 is connected to an output from the inverter gate 603. An output from the AND gate 604 is connected to a selection control input of the multiplexer 700. A data input D of the scan flip-flop 605 is connected to an output from the multiplexer 700. The scan flip-flop 605 receives the clock signal Clock. An output Q of the scan flip-flop 605 is connected to an input A of the AND gate 606.

The address control circuit 200 of the present embodiment includes a multiplexer 210, scan flip-flops 212 and 213, and a multiplexer 214, and further includes multiplexers 220 and 221, AND gates 222 and 223, and inverter gates 224 and 225. An output from the multiplexer 210 is connected to the output OUT of the address control circuit 200 and an input 1 of the multiplexer 214. An input 0 of the multiplexer 210 is connected to the input IN of the address control circuit 200. An input 1 of the multiplexer 210 is connected to an output Q of the scan flip-flop 212. A selection control input of the multiplexer 210 is connected to an output from the multiplexer 220. An input 1 of the multiplexer 220 is connected to an output Q of the scan flip-flop 213. An input 0 of the multiplexer 220 is connected to an output from the AND gate 222. A selection control input of the multiplexer 220 receives the signal RAMSEQ_En. A data input D of the scan flip-flop 212 is connected to an output from the multiplexer 214. The scan flip-flop 212 receives the clock signal Clock. The data input D of the scan flip-flop 213 receives the output Q of the scan flip-flop 213. The scan flip-flop 213 receives the clock signal Clock. An input A of the AND gate 222 is connected to an output from the AND gate 602. An input B of the AND gate 222 is connected to an output from the inverter gate 224.

The inverter gate 224 receives the signal SCAN_TEST. An input 0 of the multiplexer 214 is connected to an output from the multiplexer 221. A selection control input of the multiplexer 214 receives the signal RAMSEQ_En. An input 0 of the multiplexer 221 receives the input IN of the address control circuit 200. An input 1 of the multiplexer 221 is connected to a data output DOUT of the controller 601. A selection control input of the multiplexer 221 is connected to an output from the AND gate 223. An input A of the AND gate 223 is connected to an output from the AND gate 602. An input B of the AND gate 223 is connected to an output from the inverter gate 225. The inverter gate 225 receives the signal RAMSEQ_En.

The address signal terminal ADDR[3:0] of the RAM 100 are connected to the output OUT of the address control circuit 200. An output Q0 of the RAM 100 is connected to an input 0 of the multiplexer 700. An input 0 of the multiplexer 700 is connected to the output Q0 of the RAM 100. An input 1 of the multiplexer 700 is connected to the output OUT2 of the address control circuit 200. An output from the multiplexer 700 is connected to an input of a circuit in a subsequent stage (not shown) and a data input D of the scan flip-flop 605.

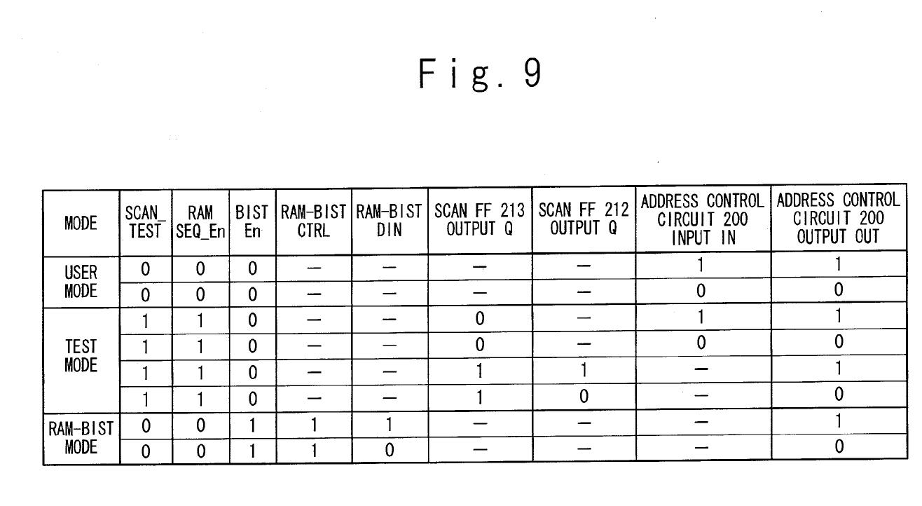

Next, an operation method of the semiconductor integrated circuit of the present embodiment will be described. FIG. 9 is a diagram showing an example of a truth table of the address control circuit 200 in the semiconductor control circuit of the present embodiment.

As described above, the semiconductor integrated circuit of the present embodiment can further perform a RAM-BIST test in addition to the transition delay fault test and the stuck-at fault test. These tests are controlled based on the signal SCAN_TEST, the signal RAMSEQ_En , and the signal BIST_En.

First, when the semiconductor integrated circuit of the present invention operates in the user mode, the logical values of the signal SCAN_TEST, the signal RAMSEQ_En, and the signal BIST_En are all set to “0”. The selection control input of the multiplexer 220 in the address control circuit 200 receives the signal RAMSEQ_En having the logical value of “0”. Since the logical value of “0” is supplied to the selection control input in the multiplexer 220, the input 0 of the multiplexer 220 is selected as the output. Also, the AND gate 602 receives at its input A1 the signal BIST_En having the logical value of “0”. Therefore, the output from the AND gate 602 always has the logical value of “0”. The output from the AND gate 602 is connected to the input A of the AND gate 222 in the address control circuit 200. The AND gate 222 always receives at its input A the logical value of “0”. Therefore, the output from the AND gate 222 always has the logical value of “0”.

The input 0 of the multiplexer 220 is connected to the output from the AND gate 222. As described above, the multiplexer 220 selects the input 0 as the output. Therefore, the output from the multiplexer 220 always has the logical value of “0”. The output from the multiplexer 220 is connected to the selection control input of the multiplexer 210. The multiplexer 210 always receives the logical value of “0” at the selection control input, and always selects the input 0 as the output. The input 0 of the multiplexer 210 is connected to the input IN of the address control circuit 200. Also, the output from the multiplexer 210 is connected to the output OUT of the address control circuit 200. Therefore, the multiplexer 210 receives at the input 0, the logical value supplied to the input IN of the address control circuit 200, and transfers the logical value from the output to the output OUT of the address control circuit 200.

The input IN of the address control circuit 200 is connected to the output from the logic circuit 300. Also, the output OUT of the address control circuit 200 is connected to the address signal terminal ADDR[3:0] of the RAM 100. Therefore, the address control circuit 200 can transfer the output from the logic circuit 300 to the address signal terminal ADDR[3:0] of the RAM 100.

Here, the AND gate 604 receives at its input A the signal SCAN_TEST having the logical value of “0”. Therefore, the output from the AND gate 604 always has the logical value of “0”. The output from the AND gate 604 is connected to the selection control input of the multiplexer 700. Therefore, the multiplexer 700 selects the input 0 as the output. The input 0 of the multiplexer 700 is connected to the output Q0 of the RAM 100. The multiplexer 700 outputs the logical value outputted from the output Q0 of the RAM 100 to a circuit in a subsequent stage.

Next, when the semiconductor integrated circuit of the present invention operates in the test mode (a transition delay fault test mode), the signal SCAN_TEST and the signal RAMSEQ_En are each set to the logical value of “1”, and the signal BIST_En is set to the logical value of “0”. The selection control inputs of the multiplexers 214 and 220 in the address control circuit 200 each receive the signal RAMSEQ_En having the logical value of “1”. When each selection control input has the logical value of “1”, the multiplexers 214 and 220 select the input 1 as the output. Here, the input 1 of the multiplexer 220 is connected to the output Q of the scan flip-flop 213. Also, the output from the multiplexer 220 is connected to the selection control input of the multiplexer 210. Based on the output from the multiplexer 220 supplied to the selection control input, the multiplexer 210 determines whether to select the input 1 or the input 2 as the output. The data input D of the scan flip-flop 213 is a feed-back input of the output Q, and outputs the set logical value to the scan flip-flop 213.

When the output Q of the scan flip-flop 213 has the logical value of “0”, the output from the multiplexer 220 also has the logical value of “0”. Since the multiplexer 210 receives the logical value of “0 ” at the selection control input, the input 0 is selected as the output. The input 0 of the multiplexer 210 is connected to the input IN of the address control circuit 200. Also, the output from the multiplexer 210 is connected to the output OUT of the address control circuit 200. Therefore, the multiplexer 210 receives at the input 0, the logical value supplied to the input IN of the address control circuit 200, and transfers the logical value from the output to the output OUT of the address control circuit 200. The input IN of the address control circuit 200 is connected to an output from the logic circuit 300. Also, the output OUT of the address control circuit 200 is connected to the address signal terminal ADDR[3:0] of the RAM 100. Therefore, the address control circuit 200 can transfer the output from the logic circuit 300 to the address signal terminal ADDR[3:0] of the RAM 100.

On the other hand, when the output Q of the scan flip-flop 213 has the logical value of “1”, the output from the multiplexer 220 also has the logical value of “1”. Since the multiplexer 210 receives the logical value of “1” at its selection control input, the multiplexer 210 selects the input 1 as the output. The input 1 of the multiplexer 214 is connected to the output Q of the scan flip-flop 212, and the data input D of the scan flip-flop 212 is connected to the output from the multiplexer 214. As described above, the multiplexer 214 selects the input 1 as the output based on the signal RAMSEQ_En having the logical value of “1”. The input 1 of the multiplexer 214 is connected to the output from the multiplexer 210. With this, the scan flip-flop 212 feeds back the output from the output Q to the data input D. Thus, the address control circuit 200 outputs the logical value set in the scan flip-flop 212 via the output OUT to the address signal terminal ADDR[3:0] of the RAM 100.

In this way, in the test mode, based on the output Q of the scan flip-flop 213, the address control circuit 200 can select whether to transfer the output from the logic circuit 300 to the address signal terminal ADDR[3:0] of the RAM 100 or output the value set in the scan flip-flop 212 to the address signal terminal ADDR[3:0] of the RAM 100, and then output the selected one.

It should be noted that the inverter gate 603 receives the signal RAMSEQ_En having the logical value of “1”. The input B of the AND gate 604 receives the logical value of “0” from the inverter gate 603. Therefore, the output from the AND gate 604 always has the logical value of “0”. The output from the AND gate 604 is connected to the selection control input of the multiplexer 700. Therefore, the multiplexer 700 selects the input 0 as the output. The input 0 of the multiplexer 700 is connected to the output Q0 of the RAM 100. The multiplexer 700 outputs the logical value outputted from the output Q0 of the RAM 100 to the circuit in the subsequent stage.

Next, when the semiconductor integrated circuit of the present invention operates in the RAM-BIST mode, the signal SCAN_TEST and the signal RAMSEQ_En are each set to the logical value of “0”, and the signal BIST_En is set to the logical value of “1”.

The AND gate 602 receives at its input A, the signal BIST_En having the logical value of “1”. Therefore, in the AND gate 602, the logical value to be outputted is determined based on the logical value of the signal supplied to the input B. The input B of the AND gate 602 is connected to the CTRL output of the controller 601. For performing the RAM-BIST test, the controller 601 outputs the logical value of “1” from the CTRL output. Therefore, the AND gate 602 receives the logical value of “1” from the CTRL output at the input B, and outputs the logical value of “1”. The output from the AND gate 602 is connected to the input A of the AND gate 222 and the input A of the AND gate 223 in the address control circuit 200. The input B of the AND gate 223 receives the signal RAMSEQ_En having the logical value inverted by the inverter gate 225. Since the signal RAMSEQ_En has the logical value of “0”, the input B of the AND gate 223 receives the logical value of “1” from the inverter gate 224. As described above, the input A of the AND gate 223 receives the logical value of “1” from the AND gate 602, and therefore the output from the AND gate 223 has the logical value of “1”. The output from the AND gate 223 is connected to the selection control input of the multiplexer 221. The multiplexer 221 outputs the input 1 as the output so as to input the logical value of “1” as a selection control input. The selection control input of the multiplexer 214 receives the signal RAMSEQ_En having the logical value of “0”, and therefore the multiplexer 214 selects the input 0 as the output.

The input B of the AND gate 222 receives the signal SCAN_TEST having the logical value inverted by the inverter gate 224. That is, since the signal SCAN_TEST has the logical value of “0”, the input B of the AND gate 222 receives the logical value of “1” from the inverter gate 224. As described above, the input A of the AND gate 222 receives the logical value of “1” from the AND gate 602, and therefore the output from the AND gate 222 has the logical value of “1”. The selection control input of the multiplexer 220 receives the signal RAMSEQ En having the logical value of “0”, and therefore selects the input 0 as the output. The input 0 of the multiplexer 220 is connected to the output from the AND gate 222. As described above, the output from the AND gate 222 has the logical value of “1”, and therefore the output from the multiplexer 220 has the logical value of “1”. The output from the multiplexer 220 is connected to the selection control input of the multiplexer 210. The multiplexer 220 receives the logical value of “1” outputted from the multiplexer 220. Therefore, the multiplexer 220 selects the input 1 as the output. The output from the multiplexer 220 is connected to the selection control input of the multiplexer 210. The multiplexer 210 receives the logical value of “1” from the multiplexer 220 at its selection control input. Therefore, the multiplexer 210 selects the input 1 as the output.

Here, the controller 601 outputs a test pattern from the test pattern output DOUT. The output DOUT from the controller 601 is connected to the input 1 of the multiplexer 221 in the address control circuit 200. As described above, the multiplexer 221 selects the input 1 as the output, and therefore outputs the logical value of the test pattern to be supplied from the output DOUT of the controller 601 to the input 1 as the output. The output from the multiplexer 221 is connected to the input 0 of the multiplexer 214. As described above, the multiplexer 214 selects the input 0 as the output, and therefore outputs the logical value of the test pattern to be supplied from the multiplexer 221 to the input 0 as the output. The output from the multiplexer 214 is connected to the data input D of the scan flip-flop 212. The scan flip-flop 212 outputs the logical value of the test pattern to be supplied from the multiplexer 214 from the output Q to the data input D. The output Q of the scan flip-flop 212 is connected to the input 1 of the multiplexer 210. As described above, the multiplexer 210 selects the input 1 as the output, and therefore outputs the logical value of the test pattern to be supplied from the scan flip-flop 212 to the input 1 as the output. The output from the multiplexer 210 is connected to the address signal terminal ADDR[3:0] of the RAM 100 via the output OUT of the address control circuit 200. Therefore, the address control circuit 200 can transfer the output from DOUT of the controller 601 to the address signal terminal ADDR[3:0] of the RAM 100 irrespectively of the output from the logic circuit 300 to be supplied to the input IN.

In this way, according to the semiconductor integrated circuit in the present embodiment, by combining the logical values of the signal SCAN_TEST, the signal RAMSEQ_En, and the signal BIST_En, any of the user mode, the test mode (transition delay fault test), and the RAM-BIST mode can be selected and performed.

Also, according to the semiconductor integrated circuit in the present embodiment, even in the test mode (transition delay fault test), the output Q of the scan flip-flop 213 in the address control circuit 200 is set to the logical value of “0”. With this, a route from the input IN to the output OUT in the address control circuit 200 can be activated. Thus, the output from the logic circuit 300 can be transferred to the address signal terminal ADDR[3:0] of the RAM 100, and the transition delay fault test can be performed on a route from the logic circuit 300 to the address signal terminal ADDR[3:0].

Furthermore, according to the semiconductor integrated circuit in the present embodiment, based on the output Q of the scan flip-flop 212, the address control circuit 200 can determine which of the logical value of “0” and “1” is to be supplied to the address signal terminal ADDR[3:0] of the RAM 100 in the test mode. Therefore, even if the logic value to be supplied is changed, the configuration of the address control circuit 200 is not required to be changed, thereby suppressing an increase in design TAT.

In addition, according to the semiconductor integrated circuit in the present embodiment, a RAM-BIST control circuit and the address control circuit for the transition delay fault test can be achieved with a simple configuration, thereby suppressing an increase in circuit size of the semiconductor integrated circuit.

### Sixth Embodiment

Next, the semiconductor integrated circuit according to a sixth embodiment of the present invention will be described.

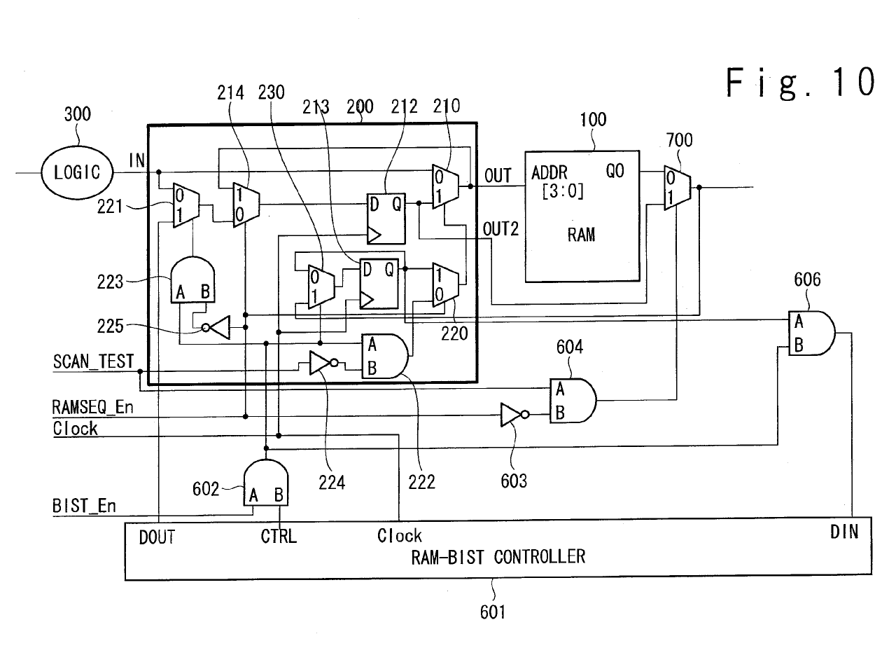

First, the configuration of the semiconductor integrated circuit in the present embodiment will be described. FIG. 10 is a diagram showing the configuration of the semiconductor integrated circuit in the present embodiment. It should be noted that the scan-chain configuration for the transition delay failure test and the scan-enable terminal are not involved in the operation of the present invention and therefore the description of them is omitted in the following description. The semiconductor integrated circuit in the present embodiment is similar to that in the fifth embodiment. Therefore, the same portions as those in the fifth embodiment are not described herein, and portions different from those in the fifth embodiment are mainly described.

As in the semiconductor integrated circuit of the fifth embodiment, the semiconductor integrated circuit in the present embodiment can further perform the RAM-BIST test in addition to the transition delay fault test and the stuck-at fault test.

The semiconductor integrated circuit in the present embodiment includes the Random Access Memory (RAM) 100, the address control circuit 200 for the RAM 100, the logic circuit 300, the RAM-BIST controller 601, AND gates 602, 604, and 606, an inverter gate 603, and the multiplexer 700. Here, as with the fifth embodiment, scan flip-flops (hereinafter referred to as scan flip-flops) 501 and 502 and an AND gate 400 are omitted in the drawing. The semiconductor integrated circuit in the present embodiment is different from that in the fifth embodiment in the configuration of the address control circuit 200, and the scan flip-flop 605 is deleted accordingly. Therefore, different portions are mainly described.

The address control circuit 200 of the present embodiment includes the multiplexer 210, the scan flip-flops 212 and 213, the multiplexer 214, the multiplexers 220 and 221, and the AND gates 222 and 223, and the inverter gates 224 and 225, and further includes a multiplexer 230. In the present embodiment, the multiplexer 230 is used also as the scan flip-flop 605 in the fifth embodiment. The output of the multiplexer 230 is connected to the output Q of the scan flip-flop 213. The input 1 of the multiplexer 230 is connected to the output from the multiplexer 700. The output from the multiplexer 230 is connected to the data input D of the scan flip-flop 213. The selection control input of the multiplexer 230 is connected to the output from the AND gate 602. Also, in the present embodiment, the scan flip-flop 605 is removed. The input A of the AND gate 606 is connected to the output Q of the scan flip-flop 213.

Next, an operation method of the semiconductor integrated circuit of the present embodiment will be described. The input and output of the address control circuit 200 in the present embodiment are similar to those as shown in a truth table of FIG. 9. However, the semiconductor integrated circuit of the present embodiment is different in configuration from that of the fifth embodiment, and therefore its operation method is different. Thus, portions different from those in the fifth embodiment will be mainly described. The operation method in the user mode in the present embodiment is similar to that in the fifth embodiment, and therefore the description is omitted.

In the test mode (transition delay fault test) of the present embodiment, as in the fifth embodiment, the signal SCAN_TEST and the signal RAMSEQ_En are set to the logical value of “1”, and the signal BIST_En is set to the logical value of “0”. The multiplexer 230 receives the logical value of “0” from the AND gate 602, and therefore selects the input 0 as the output. With this, the scan flip-flop 213 feeds back the output from the output Q to the data input D via the input 0 of the multiplexer 230, and the output Q continues to output the value set in the scan flip-flop 213. The operation method in the test mode is similar to that of the fifth embodiment except the above, and therefore the description is omitted. That is, since the multiplexer 220 receives the signal RAMSEQ_En having the logical value of “1” at the selection control input, the multiplexer 220 selects the input 1 as the output. Therefore, the multiplexer 210 selects either of the input 0 or the input 1 as the output, based on the output from the scan flip-flop 212. When the multiplexer 210 selects the input 0 as the output, the signal supplied to the input IN of the address control circuit 200 can be transferred to the output OUT. On the other hand, when the multiplexer 210 selects the input 1 as the output, the output Q of the scan flip-flop 212 can be transferred to the output OUT of the address control circuit 200.

Next, in the RAM-BIST mode of the present embodiment, as in the fifth embodiment, the signal SCAN_TEST and the signal RAMSEQ_En are set to the logical value of “0”, and the signal BIST_En is set to the logical value of “1”. Since the BIST_En signal has the logical value of “1” and the CTRL signal from the RAM-BIST controller 601 is set to the logical value of “1”, the output from the AND gate 602 has the logical value of “1”. The AND gate 223 receives the logical value of “1” from the AND gate 602 at the input A and the signal RAMSEQ_En of the logical value of “1” inverted by the inverter gate 225 at the input B, and outputs the logical value of “1”. Therefore, the multiplexer 221 receives the logical value of “1” from the AND gate 223 at the selection control input, and selects the input 1 as the output. Also, the multiplexer 214 receives the signal RAMSEQ_En having the logical value of “0” at its selection control input, and selects the input 0 as the output. Furthermore, the AND gate 222 receives the logical value of “1” from the AND gate 602 at the input A and the signal SCAN_TEST of the logical value of “1” inverted by the inverter gate 225 at the input B, and outputs the logical value of “1”. The multiplexer 220 receives the signal RAMSEQ_En having the logical value of “0” at the selection control input, and selects the input 0 as the output. The multiplexer 220 receives the logical value of “1” from the AND gate 222 at the input 0, and outputs the logical value of “1”. The multiplexer 210 receives the logical value of “1” from the multiplexer 220 at the selection control input, and therefore selects the input 1 as the output. Thus, the address control circuit 220 can transfer the output from the test pattern output DOUT of the controller 601 to the address signal terminal ADDR[3:0] of the RAM 100 irrespectively of the output from the logic circuit 300 supplied to the input IN.

Furthermore, the multiplexer 230 receives the logical value of “1” from the AND gate 602 at the selection control input, and therefore selects the input 1 as the output. The input 1 of the multiplexer 230 is connected to the output from the multiplexer 700. The multiplexer 700 receives the logical value of “0” from the AND gate 604 at the selection control input, and selects the input 0 as the output. Therefore, the output from the output Q0 of the RAM 100 is supplied to the multiplexer 700 and the data input D of the scan flip-flop 213 via the multiplexer 230. The output Q of the scan flip-flop 213 is connected to the input A of the AND gate 606. The input B of the AND gate 606 receives the logical value of “1” from the AND gate 602, and therefore the value corresponding to the output Q of the scan flip-flop 213 can be transferred to the test pattern input DIN of the controller 601.

In this way, according to the semiconductor integrated circuit in the present embodiment, by combining the logical values of the signal SCAN_TEST, the signal RAMSEQ_En, and the signal BIST_En, any of the user mode, the test mode (transition delay fault test), and the RAM-BIST mode can be selected and performed.

Also, according to the semiconductor integrated circuit in the present embodiment, even in the test mode (transition delay fault test), the output Q of the scan flip-flop 213 in the address control circuit 200 is set to the logical value of “0”. With this, a route from the input IN to the output OUT in the address control circuit 200 can be activated. Thus, the output from the logic circuit 300 can be transferred to the address signal terminal ADDR[3:0] of the RAM 100, and the transition delay fault test can be performed on a route from the logic circuit 300 to the address signal terminal ADDR[3:0].

Furthermore, according to the semiconductor integrated circuit in the present embodiment, based on the output Q of the scan flip-flop 212, the address control circuit 200 can determine which of the logical value of “0” and “1” is to be supplied to the address signal terminal ADDR[3:0] of the RAM 100 in the test mode. Therefore, even if the logic value to be supplied is changed, the configuration of the address control circuit 200 is not required to be changed, thereby suppressing an increase in design TAT.

In addition, according to the semiconductor integrated circuit in the present embodiment, the RAM-BIST controller and the address control circuit for the transition delay fault test can be achieved with a simple configuration, thereby suppressing increase in circuit size of the semiconductor integrated circuit.

The semiconductor integrated circuit of the present invention has been described. A first effect of the semiconductor integrated circuit of the present invention is in that the route from the logic circuit 300 to the address signal terminal ADDR[3:0] of the RAM 100 via the address control circuit 200 can be activated. Therefore, the transition delay fault test can be performed on the route from the address control circuit 200 for the RAM 100 to the address signal terminal ADDR[3:0] of the RAM 100. A second effect of the semiconductor integrated circuit of the present invention is in that a burden of wiring due to the provision of an observation scan flip-flop for the stuck-at fault test can be reduced. A third effect of the semiconductor integrated circuit of the present invention is in that the address control circuit 200 can be achieved by adding multiplexers and scan flip-flops to the RAM-BIST controller.

While the present invention has been described by referring to the embodiments, the present invention is not limited to the above-described embodiments, and the configuration and detail of the present invention can be variously modified as being understandable to those skilled in the art within the range of the present invention.

What is claimed is:

1. A semiconductor integrated circuit comprising:
a memory;
a logic circuit configured to output an address signal for an address of said memory; and
an address control circuit connected with said logic circuit and an address terminal of said memory, and configured to receive a test signal to output one of the address signal from said logic circuit and an output signal having a preset logical value to said address terminal of said memory based on the test signal,
wherein the test signal indicates one of a user mode in which a transfer delay fault test is not performed and a test mode in which the transfer delay fault test is performed on a path from said logic circuit to said address terminal of said memory.

2. The semiconductor integrated circuit according to claim 1, wherein said address control circuit comprises:
a scan flip-flop configured to output said output signal;
a NAND gate configured to receive the test signal and said output signal, and output said output signal when the test signal indicates the test mode; and
an AND gate configured to receive the address signal from said logic circuit and said output signal from said NAND gate and output one of the address signal and said output signal to said address terminal of said memory based on said output signal.

3. The semiconductor integrated circuit according to claim 2, wherein said address control circuit further comprises:
a multiplexer configured to receive as data inputs, the address signal from said logic circuit and said output signal from said scan flip-flop, receive the test signal as a selection input, output said output signal to said scan flip-flop when the test signal indicates the test mode, and output the address signal to said scan flip-flop when the test signal indicates the user mode.

4. The semiconductor integrated circuit according to claim 1, wherein said address control circuit comprises:
a first scan flip-flop configured to output said output signal;
a first multiplexer configured to receive the address signal from said logic circuit and said output signal from said first scan flip-flop as data inputs and a first selection signal a selection input and output one of the address signal and said output signal to said address terminal of said memory in response to the first selection signal;
a second scan flip-flop configured to output a selection signal having a preset logical value; and
an AND gate configured to receive the test signal and the selection signal from said second scan flip-flop, and output the first selection signal to said first multiplexer when the test signal indicates the test mode.

5. The semiconductor integrated circuit according to claim 4, wherein said address control circuit further comprises:
a second multiplexer configured to receive the address signal from said logic circuit and said output signal from said first scan flip-flop as data inputs and the test signal as a selection input, and output said output signal to said first scan flip-flop when the test signal indicates the test mode, and output the address signal to said first scan flip-flop when the test signal indicates the user mode.

6. The semiconductor integrated circuit according to claim 1, further comprising:
a controller configured to output a test pattern and a BIST control signal for a BIST (Built In Self Test) test on said memory,
wherein said address control circuit receives a BIST test signal and said test pattern from said controller and outputs the test pattern to said address terminal of said memory, when the BIST test signal indicates a BIST test mode in which the BIST test is performed on said memory.

7. The semiconductor integrated circuit according to claim 6, further comprising:
an AND gate configured to receive an output signal from said memory and the BIST test signal and supply the output signal from said memory to said controller when the BIST test signal indicates the BIST test mode.

8. The semiconductor integrated circuit according to claim 6, wherein said address control circuit comprises:
a first scan flip-flop configured to output a preset signal having a preset logic value;
a first multiplexer configured to receive the preset signal from said first scan flip-flop and the BIST test signal as data inputs and the test signal as a selection input, and output as a selection signal, the preset signal from said first scan flip-flop in the test mode and the BIST test signal in the BIST test mode;
a second scan flip-flop configured to output said output signal based on an input data;
a second multiplexer configured to receive the address signal from said logic circuit and said output signal from said second scan flip-flop as data inputs and the selection signal from said first multiplexer as a selection input, and output to said address terminal of said memory based on the selection signal from said first multiplexer, the address signal from said logic circuit when the normal mode is set and said output signal from said second scan flip-flop when the normal mode is not set,
a third multiplexer configured to output the address signal from said logic circuit when the BIST test mode is not set and the test pattern from said controller when the BIST test mode is set; and
a fourth multiplexer configured to output to said second flip-flop as the input data, an output of said second multiplexer when the test mode is set and an output of said third multiplexer when the test mode is not set.

9. The semiconductor integrated circuit according to claim 8, wherein said address control circuit further comprises:
a fifth multiplexer having an output connected with a data input of said first scan flip-flop, and configured to receive the preset signal from said first scan flip-flop and an output signal from said memory, and output the preset signal when the BIST test mode is set and the output signal from said memory when the BIST test mode is set, and
wherein said semiconductor integrated circuit further comprises:
an AND gate configured to output the output signal from said first flip-flop to said controller when the BIST test mode is set.

10. A test method of a semiconductor integrated circuit, comprising:
receiving an address signal for an address of a memory from a logic circuit, an output signal having a preset logical value and a test signal;
selecting one of the address signal and said output signal based on the test signal; and
outputting the selected signal to an address terminal of said memory,
wherein the test signal indicates one of the user mode in which a transfer delay fault test is not performed and a test mode in which the transfer delay fault test is performed on a path from said logic circuit to said address terminal of said memory, and
wherein the address signal is selected in a user mode and said output signal is selected in a test mode.

11. The test method according to claim 10, wherein said selecting comprises:
generating said output signal from a scan flip-flop;
outputting said output signal from a NAND gate when the test signal indicates the test mode; and
selecting the address signal by an AND gate in the user mode; and
selecting said output signal by said AND gate in the test mode.

12. The test method according to claim 11, wherein said outputting said output signal from a scan flip-flop comprises:
outputting said output signal from a multiplexer to said scan flip-flop when the test signal indicates the test mode; and
outputting the address signal from said multiplexer to said scan flip-flop when the test signal indicates the user mode.

13. The test method according to claim 10, wherein said selecting comprises:
generating said output signal from a first scan flip-flop;
generating a selection signal having a preset logical value from a second scan flip-flop;
outputting the selection signal from an AND gate to a first multiplexer when the test signal indicates the test mode; and
selecting one of the address signal outputted from said logic circuit and said output signal outputted from said first scan flip-flop in response to the selection signal in said first multiplexer.

14. The test method according to claim 13, wherein said generating said output signal from a first scan flip-flop further comprises:
receiving said output signal from said first scan flip-flop by a second multiplexer; and
outputting said output signal from the second multiplexer to said first scan flip-flop when the test signal indicates the test mode; and
outputting the address signal from the second multiplexer to said first scan flip-flop when the test signal indicates the user mode.

15. The test method according to claim 10, further comprising:
outputting a test pattern and a BIST control signal for a BIST (Built In Self Test) test on said memory from a controller;
wherein said selecting further comprises:
selecting the test pattern, when a BIST test signal indicates a BIST test mode in which the BIST test is performed on said memory.

16. The test method according to claim 15, further comprising:
supplying the output signal outputted from said memory to said controller by an AND gate when the BIST test signal indicates the BIST test mode.

17. The test method according to claim 15, wherein said selecting comprises:
generating a preset signal having a preset logic value from a first scan flip-flop;
outputting from a first multiplexer as a selection signal, the preset signal in the test mode and the BIST test signal in the BIST test mode;
generating said output signal from a second scan flip-flop based on an input data;
selecting based on the selection signal from said first multiplexer, the address signal outputted from said logic circuit when the normal mode is set and said output signal from said second scan flip-flop when the normal mode is not set;
selecting in a third multiplexer, the address signal outputted from said logic circuit when the BIST test mode is not set and the test pattern outputted from said controller when the BIST test mode is set; and
outputting to said second flip-flop as the input data, an output of said second multiplexer when the test mode is set and an output of said third multiplexer when the test mode is not set.

18. The test method according to claim 17, wherein said selecting further comprises:
outputting from a fifth multiplexer to said first scan flip-flop, the preset signal outputted from said first scan flip-flop when the BIST test mode is set and the output signal outputted from said memory when the BIST test mode is set, and
wherein said test method further comprises:
outputting the output signal from said first flip-flop to said controller when the BIST test mode is set.
